(19) United States
(12) Patent Application Publication
(10) Pub. No.: US 2010/0068853 A1
(43) Pub. Date: Mar. 18, 2010

(54) METHOD OF MANUFACTURING SEMICONDUCTOR DEVICE

(75) Inventor: Wataru TAKAMATSU, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Kawasaki (JP)

(21) Appl. No.: 12/561,003

(22) Filed: Sep. 16, 2009

(30) Foreign Application Priority Data
Sep. 17, 2008 (JP) 2008-238103

(51) Int. Cl. H01L 21/78; H01L 21/50

(52) U.S. Cl. 438/113; 438/124; 257/E21.499; 257/E21.599

(57) ABSTRACT

In a method of manufacturing a semiconductor device, a substrate having first electrodes on a main surface thereof and a semiconductor chip having second electrodes on a first main surface thereof are arranged such that the main surface of the substrate and the first main surface of the semiconductor chip oppose to each other, and the first electrodes and the second electrodes are connected so as to electrically connect the substrate and the semiconductor chip. The semiconductor chip is made thin by grinding a second main surface opposing to the first main surface of the semiconductor chip which is connected with the substrate. Side surfaces and the second main surface of the semiconductor chip made thin are sealed with resin.

### INCORPORATION BY REFERENCE

This patent application claims a priority on convention based on Japanese Patent Application No. 2008-238103. The disclosure thereof is incorporated herein by reference.

### BACKGROUND OF THE INVENTION

1. Field of the Invention

The present invention relates to a method of manufacturing a resin sealed type of semiconductor device.

2. Description of Related Art

In a Ball Grid Array (BGA) package to realize a multi-pin type of semiconductor device and an excellent electronic characteristic thereof, the thickness of a package is determined depending on the thicknesses of a semiconductor chip allocated in the package. The package has a certain thickness since a defect such as a crack may be generated in a dicing step in the assembly of a semiconductor device unless the semiconductor chip has a certain degree of thickness. However, in order to mount a high-performance chip in a limited space, a further thinning of a package is a necessary technique.

A method of manufacturing semiconductor device by using a package thinning technique is described in Japanese Patent Application Publication No. 2004-158739. The method is shown in FIGS. 3A to 3F. FIG. 3A shows a bonding step of semiconductor chips. As shown in FIG. 3A, a substrate 1 such as a polyimide substrate having electrodes made of Au on its surface and semiconductor chips 4 having bumps 3 made of Au on its surface are prepared. By arranging the semiconductor chips 4 in such a manner that their surfaces face the surface of the substrate 1, the electrodes of the substrate 1 are connected to the bumps 3 so as to bond the semiconductor chips 4 to the substrate 1. After that, the surface of the substrate 1 facing the bumps 3 thereon, side surfaces of the semiconductor chips 4, and rear surfaces of the semiconductor chips 4 are molded with an epoxy resin 5.

Next, as shown in FIG. 3B, by grinding the resin 5 on the rear surfaces of the semiconductor chips 4 by a grinder 6, the rear surfaces of the semiconductor chips 4 are exposed. Then, as shown in FIG. 3C, the semiconductor chips 4 are thinned to about 50 μm, for example. According to this step, the rear surfaces of the semiconductor chips 4 and the surface of the resin 5 are formed on a same plane.

Then, as shown in FIG. 3D, as a conductive film, a metal layer 7 is formed on the rear surfaces of the semiconductor chips 4 and the surface of the resin 5 of the opposite side portions of each of the semiconductor chips 4. This metal layer 7 is formed to have a laminate structure having a TiN layer of 100 ·m or less and an Au layer of about 50 ·m, in order to maintain an adhesion. Further, the metal layer 7 may be made of other metal or a metal compound, and a resin layer may be formed in place of the metal layer 7.

At last, as shown in FIG. 3E, by grinding the space between the semiconductor chips by using a dicing saw 8, semiconductor devices of a resin sealed type are individually diced, as shown in FIG. 3F. In the resin sealed type of semiconductor device diced by this dicing step, any surfaces of the semiconductor chip 4 are not exposed.

However, according to such a method, as shown in FIG. 3D, the metal layer 7 should be formed after grinding the resin 5 and the semiconductor chips 4. In this case, because of a stress caused by change in a temperature of the resin sealed type of semiconductor device, a difference in a coefficient of thermal expansion between the metal layer 7 and the resin 5 may involve a problem of adhesion of the semiconductor chips 4 and their peripheral parts.

### SUMMARY OF THE INVENTION

In an aspect of the present invention, a method of manufacturing a semiconductor device is achieved by arranging a substrate having first electrodes on a main surface thereof and a semiconductor chip having second electrodes on a first main surface thereof such that the main surface of the substrate and the first main surface of the semiconductor chip oppose to each other and connecting the first electrodes and the second electrodes so as to electrically connect the substrate and the semiconductor chip; by making the semiconductor chip thin by grinding a second main surface opposing to the first main surface of the semiconductor chip which is connected with the substrate; and by sealing side surfaces and the second main surface of the semiconductor chip made thin, with resin.

In another aspect of the present invention, a method of manufacturing a semiconductor device is achieved by mounting a semiconductor chip having a predetermined thickness above a substrate such that the semiconductor chip is electrically connected with the substrate; by grinding the semiconductor chip to a thickness thinner than the predetermined thickness; and by sealing the substrate and the semiconductor chip with resin to cover the main surface of the substrate and the semiconductor chip.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a diagram showing a structure of a resin sealed type of semiconductor device according to an embodiment of the present invention;

FIGS. 2A to 2F are sectional views showing a manufacturing method of the resin sealed type of semiconductor device according to the embodiment of the present invention; and

FIGS. 3A to 3F are sectional views showing a conventional manufacturing method of the resin sealed type of semiconductor device.

### DESCRIPTION OF THE PREFERRED EMBODIMENTS

Hereinafter, a method of manufacturing a resin sealed type of semiconductor device according to the present invention will be described with reference to the attached drawings.

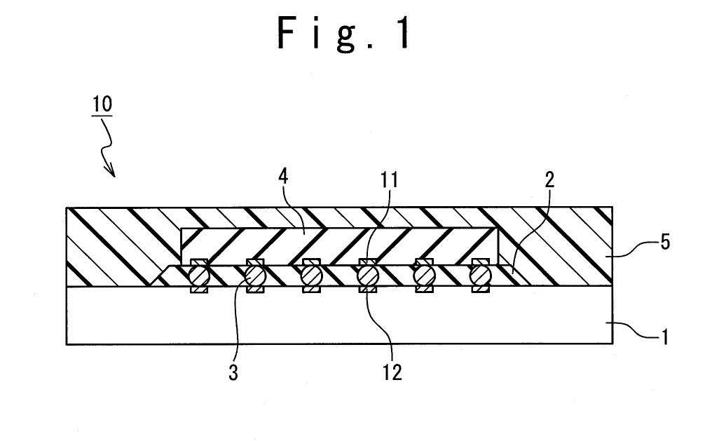

FIG. 1 is a sectional view showing a structure of a resin sealed type of semiconductor device 10 according to an embodiment of the present invention. As shown in FIG. 1, the resin sealed type of semiconductor device 10 according to the present embodiment is provided with a substrate 1, an underfill 2, bumps 3, a semiconductor chip 4, and a resin 5.

First electrodes 12 made of Au are formed on a surface (a main surface) of the substrate 1 such as a polyimide substrate. In addition, second electrodes 11 are formed on the surface (a first main surface) of the semiconductor chip 4, and the bumps 3 made of Au are formed on the second electrodes 12. The first main surface of the semiconductor chip 4 and the main surface of the substrate 1 are arranged so as to face to each other. In addition, the substrate 1 and the semiconductor chip 4 are bonded with each other via the underfill 2 such as a resin, and the first electrodes 12 of the substrate 1 and the second electrodes 11 are connected via the bumps 3. In other words, the semiconductor chip 4 is mounted on the substrate 1 facedown.

Epoxy resin 5 is formed on the main surface (the surface on the part of the bumps 3) of the substrate 1 so as to cover the semiconductor chip 4. In other words, the main surface of the substrate 1, and the side surfaces and the rear surface (the second main surface) of the semiconductor chip 4 are molded with the resin 5. Further, the semiconductor chip 4 is thinned to about 50 ·m, for example.

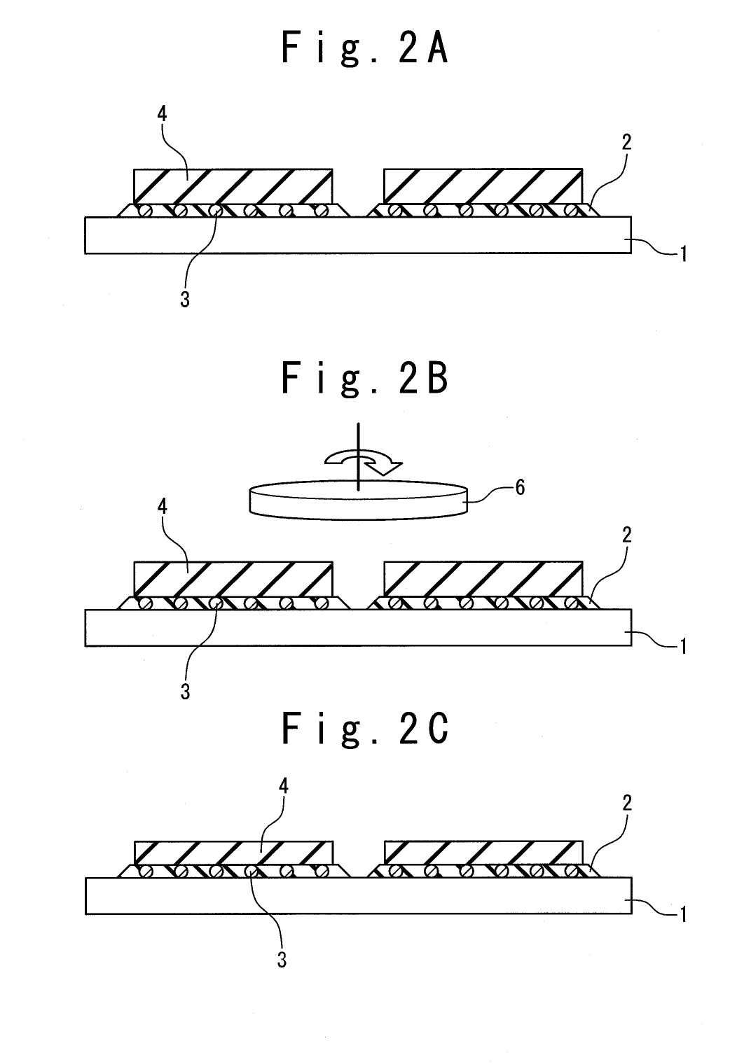

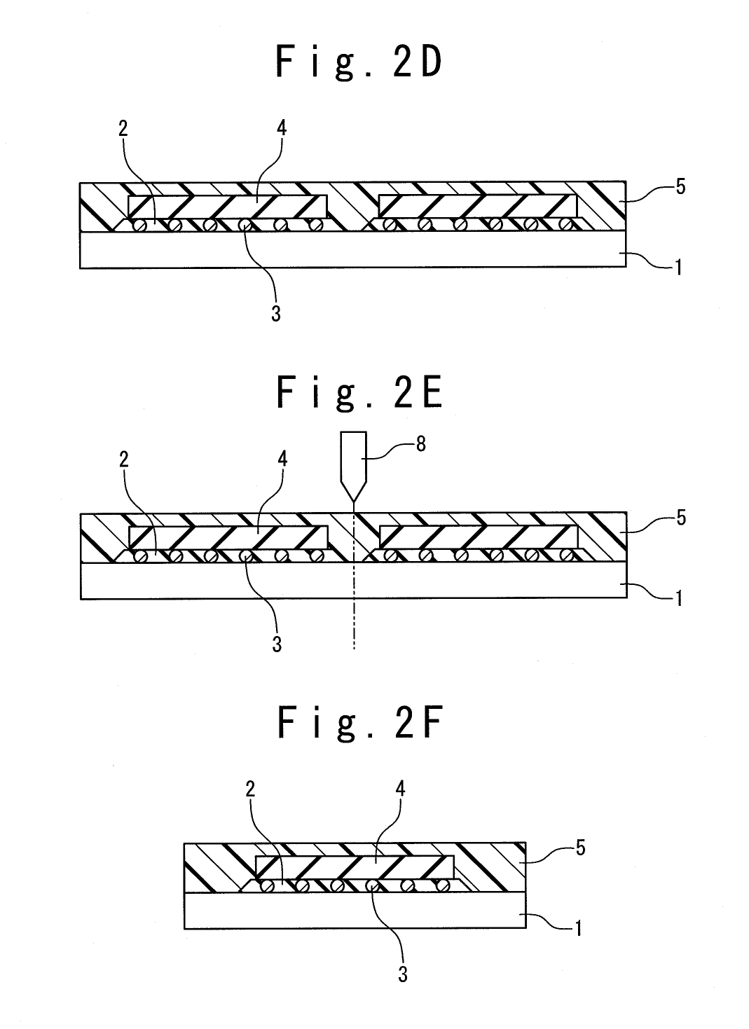

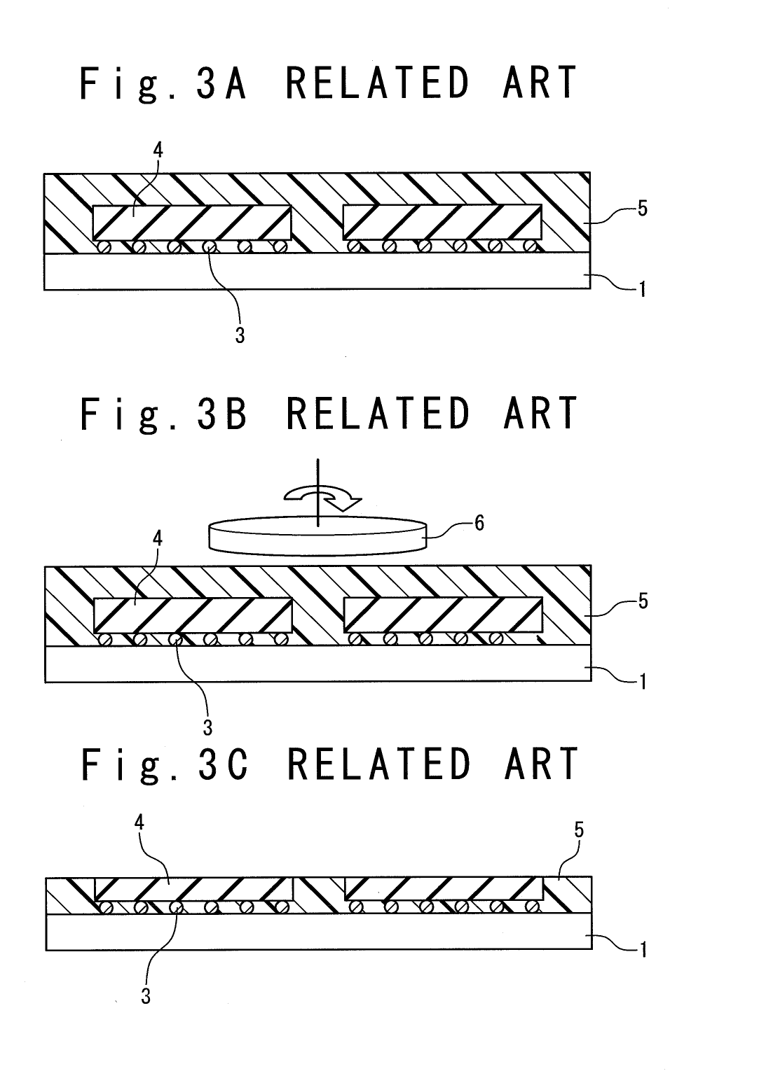

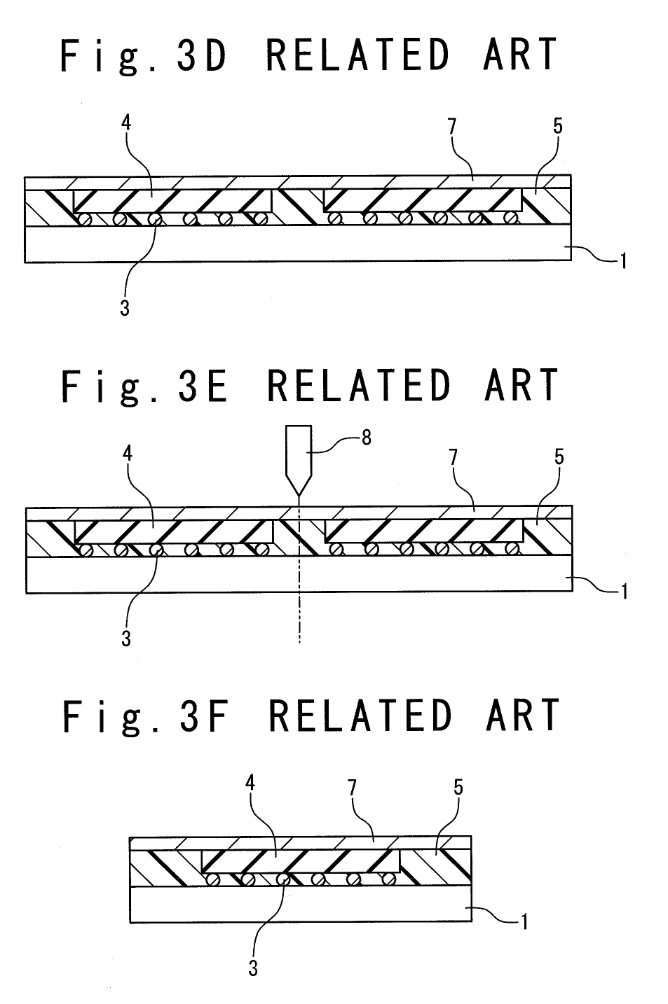

Here, referring to FIGS. 2A to 2F, a method of manufacturing the resin sealed type of semiconductor device 10 according to the embodiment of the present invention will be described. FIGS. 2A to 2F are sectional views in the manufacturing method of the resin sealed semiconductor device 10 according to the present embodiment. In this case, an example such that two semiconductor chips 4 are bonded with each other on the substrate 1 is illustrated.

FIG. 2A shows a bonding step of the semiconductor chips. As shown in FIG. 2A, at first, the substrate 1 having the first electrodes 12 on the surface thereof and the semiconductor chips 4 having the bumps 3 on the second electrodes 12 are prepared. Each of the semiconductor chips 4 has a predetermined thickness. Then, by arranging the semiconductor chips 4 in such a manner that their surfaces face the surface of the substrate 1, the first electrodes 12 of the substrate 1 are connected to the second electrodes 11 via the bumps 3. Thereby, the semiconductor chips having predetermined thicknesses are mounted on the substrate 1. Then, the semiconductor chips 4 are bonded to the substrate 1 by forming the underfill 2 in the gap between the substrate 1 and each of the semiconductor chips 4.

Next, as shown in FIG. 2B, by grinding the rear surfaces of the semiconductor chips 4 by using a grinder 6, the semiconductor chips 4 are thinned more than the above-described predetermined thicknesses as shown in FIG. 2C. For example, the semiconductor chips 4 are thinned to about 50 ·m, for example.

Subsequently, as shown in FIG. 2D, the resin 5 is formed so as to cover a plurality of the semiconductor chips 4. Depending on this step, the side surfaces and the rear surfaces of the semiconductor chips 4 are covered with the resin 5, and any surfaces of the semiconductor chip 4 are not exposed. In other words, the surfaces of the semiconductor chips 4 except for the surfaces connected with the substrate 1 are covered with the resin 5. In addition, a region not covered with the semiconductor chips 4 on the surface of the substrate 1 are also covered with the resin 5.

Finally, by grinding the gap between the semiconductor chips 4 by using a dicing saw 8 as shown in FIG. 2E, the resin sealed type of semiconductor devices 10 are individually diced as shown in FIG. 2F. Even after this dicing step, in each of the resin sealed type of semiconductor devices 10, any surfaces of the semiconductor chips 4 are covered with the resin 5 and they are not exposed.

In this manner, the resin sealed type of semiconductor device 10 according to the present invention is constructed in such a manner that the semiconductor chips 4 are bonded to the substrate 1, and after dicing the semiconductor chips 4, any surfaces of the semiconductor chips 4 are covered with the resin 5 so that any surfaces of the semiconductor chips 4 are not exposed. Therefore, there is no need to form another film after dicing the semiconductor chips 4, and the semiconductor chips 4 can be collectively covered with the resin 5. This provides an effect that no boundary face exists between the resin 5 and another layer and the resin itself has an excellent adhesion with respect to the semiconductor chips, unlike a conventional case.

As described above, according to the present invention, as compared to a conventional manufacturing method of the resin sealed type of semiconductor device in which a metal film is formed after dicing of the semiconductor chips, the adhesion between the semiconductor chips and the resin can be improved. In addition, according to the present invention, the conventional step of forming a metal layer can be omitted, and this makes it possible to simplify the manufacturing method of the resin sealed semiconductor device.

Although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. A method of manufacturing a semiconductor device comprising:
arranging a substrate having first electrodes on a main surface thereof and a semiconductor chip having second electrodes on a first main surface thereof such that the main surface of said substrate and the first main surface of said semiconductor chip oppose to each other and connecting said first electrodes and said second electrodes so as to electrically connect said substrate and said semiconductor chip;
making said semiconductor chip thin by grinding a second main surface opposing to the first main surface of said semiconductor chip which is connected with said substrate; and
sealing side surfaces and said second main surface of said semiconductor chip made thin, with resin.

2. The method according to claim 1, wherein a plurality of said semiconductor chips are connected to said substrate, and
said method further comprises:
individually dicing said plurality of semiconductor chips after said sealing of said plurality of semiconductor chips with said resin.

3. The method according to claim 1, further comprising:
forming underfill in a space between the main surface of said substrate and the first main surface of said semiconductor chip.

4. The method according to claim 2, further comprising:
forming underfill in a space between the main surface of said substrate and the first main surface of each of said plurality of semiconductor chips.

5. A method of manufacturing a semiconductor device comprising:
mounting a semiconductor chip having a predetermined thickness above a substrate such that said semiconductor chip is electrically connected with said substrate;
grinding said semiconductor chip to a thickness thinner than the predetermined thickness; and
sealing said substrate and said semiconductor chip with resin to cover the main surface of said substrate and said semiconductor chip.
